(19) United States
(12) Patent Application Publication
(10) Pub. No.: US 2026/0253842 A1
(43) Pub. Date: Aug. 27, 2026

(54) METHOD FOR DRY ETCHING COPPER THIN FILM

(71) Applicant: AP SYSTEMS INC., Hwaseong-si (KR)

(72) Inventors: Jin Nyoung JANG, Yongin-si (KR); Jong Hwa LEE, Incheon (KR); Sang Heon LEE, Sejong-si (KR); Yun Sung JANG, Yongin-si (KR); Hak Rae KIM, Pyeongtaek-si (KR); Seong Joon CHO, Gwangju-si (KR)

(21) Appl. No.: 19/574,948

(22) Filed: Mar. 23, 2026

Related U.S. Application Data
(63) Continuation of application No. PCT/KR2024/014416, filed on Sep. 24, 2024.

(30) Foreign Application Priority Data
Sep. 26, 2023 (KR) 10-2023-0128854
Sep. 6, 2024 (KR) 10-2024-0121472

(51) Int. Cl. H01J 37/32

(52) U.S. Cl. CPC H01J 37/3244; H01J 2237/3341

(57) ABSTRACT

The present invention relates to a method for dry etching a copper thin film by using plasma processing, and the technical subject matter is a method for dry etching a copper thin film by using plasma etching, the method having an XH_{y} type second etching gas supplied in order to increase the reactivity between hydrogen atoms and copper chloride (CuClₓ), which is generated during copper thin film etching using an ACl_{b} type first etching gas.

### TECHNICAL FIELD

The present disclosure relates generally to a method for dry etching a copper thin film by using plasma processing. More particularly, the present disclosure relates to a method for dry etching a copper thin film, in which copper chloride resulting from plasma etching of the copper thin film is efficiently removed by enhancing the reactivity between the copper chloride and hydrogen atoms.

A Korean national and development project supported by the Korean government associated with the present invention is described below:
Project Unique Number: 1415184827
Project Serial Number: 20016358
Government Department: Ministry of Trade, Industry and Energy
Specialized Institution for Project Management: Korea Planning & Evaluation Institute of Industrial Technology
Research Program Title: Electronic Components Industry Technology Development-Establishment of Display Innovation Process Platform
Project Title: Development of Dry Etching Process Equipment Technology for Copper Thin Films for Low-Resistance Fine Metal Wiring in High-Resolution AMOLED Displays
Performing Institute: APS Research Co., Ltd.
Research Period: Apr. 1, 2021 to Dec. 31, 2024

### BACKGROUND ART

The display industry, which represents one of South Korea's flagship industries, has continuously grown on the basis of amorphous silicon (a-Si) TFT-LCD technology and low-temperature polycrystalline silicon (LTPS)-based small-size AMOLED technology. South Korea has maintained a leading position in the global market not only in TFT-LCD and AMOLED sectors, with world-class production capabilities, but also across upstream businesses such as materials, components, and equipment required for TFT-LCD and AMOLED panel fabrication, as well as downstream markets including smart devices and digital televisions incorporating LCD and OLED panels.

However, in the current situation the shift of TFT-LCD market leadership to China, fueled by intensified national-level investment, has weakened the profitability of the display industry, thus it is imperative to increase research and investment in next-generation display technologies beyond succeeding AMOLED, in which Korea presently holds a competitive advantage, in order to maintain the status of the display industry as a strategic pillar of the Korean economy and to secure absolute global competitiveness.

The core of next-generation display technologies beyond silicon-based TFT-LCD and AMOLED is expected to be ultra-high-resolution displays, including Plastic AMOLED. In particular, flexible AMOLED technology for AR/MR wearable displays with ultra-high resolution (at least 1,000 ppi or higher), which transcends the current limitations of small-sized Plastic AMOLED, is anticipated to become one of the main axes of the display industry over the next decade.

Recently, as the demand for ultra-high-resolution AMOLED panels has rapidly increased in mobile/IT displays, including displays for AR/MR applications, fine patterning technology for low-resistance wiring has emerged as a critical technology for realizing ultra-high-resolution panels.

In order to fabricate high-resolution large-area displays, particularly ultra-high-resolution AMOLED panels requiring multiple wiring layers, reducing electrode wiring widths is required, and transitioning to copper (Cu) wiring with high electrical conductivity is therefore essential. However, conventional wet etching processes suffer from substantial limitations in fine-wiring patterning at the 1 to 2 μm scale, making dry etching technology indispensable.

Nevertheless, a copper chloride (CuClₓ) etching compound resulting from the reaction between Cu and chlorine (Cl) gas, which is a representative halogen gas used in dry etching of copper thin films, exhibits extremely a high vaporization temperature exceeding 1,300° C. at atmospheric pressure. To vaporize this by-product, substrate heating to a temperature above 400° C. is required under a typical RIE-mode dry etching pressure of approximately 50 mTorr. Even at an extremely low pressure below 1.5 mTorr, which is difficult to implement in capacitively coupled plasma (CCP) systems including RIE mode, a substrate temperature exceeding 200° C. is still required.

To overcome these drawbacks, several technologies have been proposed and developed to date, including:
1) A method in which a copper thin film is irradiated with Cl plasma to form a porous CuClₓ etching compound, which is subsequently removed using an HCl solution;
2) A method in which a copper thin film is reacted with Cl plasma to form a CuClₓ etching compound, which is subsequently removed by forced vaporization by supplying additional heating energy, such as substrate heating above 400° C. or irradiation with ultraviolet (UV) or infrared (IR) light;
3) A method employing a high-density plasma (HDP) source operating at an extremely low pressure below 5 mTorr to establish plasma conditions under which the generated CuClₓ etching compound can be readily vaporized;
4) A method using CH₃COOH/Ar or CH₃OH/Ar gas as etching gas, which enables the formation of CuH-based etching compound that is readily vaporized above a predetermined temperature.

However, the method 1) involves forming solid-phase copper chloride (CuClₓ) via a dry process, followed by an additional wet process using an HCl solution, making it impossible to avoid the fundamental limitations of wet etching for fine patterning and resulting in increased process complexity.

The method 2) requires a substrate temperature exceeding 400° C., making it difficult to avoid deformation of glass substrates and degradation of TFT thin-film properties. Furthermore, achieving process uniformity over large-area substrates is extremely challenging, and forcibly vaporized etching by-products inevitably re-deposits on a process chamber or vacuum pump maintained at a relatively low temperature.

The method 3) requires a high-temperature, high-density plasma capable of achieving an etch rate exceeding 100 nm/min at an extremely low pressure below 5 mTorr. However, no HDP source capable of uniformly generating such plasma over large-area substrates of 8th-generation class and higher currently exists.

Although experimental results have been reported in which the method 4) successfully dry-etched copper electrode wiring for semiconductor applications, its low etch rate and difficulty in process gas handling limit its applicability to large-area display fields.

Accordingly, the copper thin-film dry etching technologies studied to date are insufficient for application to mass production of 6th-generation large-area panels for high-resolution AMOLED displays, and there remains a strong demand for a new alternative technology.

### SUMMARY

### Technical Problem

Accordingly, the present disclosure has been made keeping in mind the above problems occurring in the related art, and an objective of the present disclosure is to provide a method for dry etching a copper thin film, the method being capable of efficiently removing copper chloride resulting from plasma etching of the copper thin film by enhancing the reactivity between the copper chloride and hydrogen atoms.

### Technical Solution

In order to accomplish the above objective, the present disclosure provides a method for dry etching a copper thin film by using plasma etching, wherein during copper thin film etching using an ACl_{b}-type first etching gas, an XH_{y}-type second etching gas may be supplied to enhance reactivity between copper chloride (CuClₓ) resulting from the copper thin film etching and hydrogen atoms.

Additionally, the ACl_{b}-type first etching gas may be any one selected from HCl, Cl₂, BCl₃, and CCl₄, or a mixture of at least two thereof.

Additionally, the XH_{y}-type second etching gas may be any one selected from NH₃, CH₄, C₂H₄, C₃H₈, C₄H₁₀, and CₘHₙ, or a mixture thereof.

Additionally, a plasma generated by supplying the ACl_{b}-type first etching gas and the XH_{y}-type second etching gas may satisfy the following relationship: 0.5N(Cl+)≤N(H+), wherein N(H+) may denote a flux of H⁺ ions and N(Cl+) may denote a flux of Cl⁺ ions.

Additionally, a reaction between the copper chloride (CuClx) and hydrogen atoms may be represented by the following reaction equations: Cu+Cl->CuClₓ (solid), 3CuClₓ (solid)+3H (gas)->Cu₃Cl₃ (gas)+3HCl (gas).

Additionally, as a process temperature of the plasma etching decreases, a formation rate of Cu₃Cl₃ may become faster than a formation rate of the copper chloride.

Additionally, the reactivity between the copper chloride and hydrogen atoms may be enhanced by increasing an electron temperature (Te).

### Advantageous Effects

According to a method for dry etching a copper thin film by using plasma etching of the present disclosure, removal of copper chloride resulting from plasma etching of the copper thin film is achieved by enhancing the reactivity between the copper chloride and hydrogen atoms.

In particular, by additionally or simultaneously supplying an ACl_{b}-type first etching gas and an XH_{y}-type second etching gas during the etching process, plasma flux (i.e., the ratio of radicals) control is realized, thereby promoting a reaction between copper chloride and hydrogen atoms that outpaces the formation of copper chloride and thus enabling efficient removal of copper chloride.

Furthermore, by rapidly removing copper chloride through control of ion flux, the need for cumbersome processes such as wet etching steps or high-temperature/auxiliary energy inputs conventionally required for copper chloride removal is eliminated, while simultaneously suppressing problems associated with chamber contamination caused by re-condensation during forced vaporization of copper chloride.

### BRIEF DESCRIPTION OF DRAWINGS

FIG. 1 is a table illustrating changes in etch rate as a function of the flow rate of HCl+H₂ gas under identical power conditions.

FIG. 2 is a table illustrating changes in etch rate under identical power conditions for an HCl etching gas and for an HCl+NH₃ etching gas including added NH₃.

FIG. 3 is a graph comparing changes in etch rate of a copper thin film resulting from an increase in total gas flow rate and from addition of NH₃ gas.

### DETAILED DESCRIPTIONS OF EXEMPLARY EMBODIMENTS

The present disclosure relates to a method for dry etching a copper thin film by using plasma etching, in which copper chloride resulting from plasma etching of the copper thin film is removed by enhancing the reactivity between the copper chloride and hydrogen atoms.

In particular, the present disclosure controls plasma flux (i.e., the ratio of radicals) by additionally or simultaneously supplying a ACl_{b}-type first etching and a an XH_{y}-type second etching during plasma etching to induce a reaction between generated copper chloride and hydrogen atoms that proceeds faster than the formation of copper chloride, thereby enabling efficient removal of copper chloride.

The method for dry etching the copper thin film by using plasma etching of the present disclosure is characterized by, during copper thin film etching using an ACl_{b}-type first etching gas, an XH_{y}-type second etching gas is supplied so as to enhance the reactivity between copper chloride (CuClₓ) resulting from the etching and hydrogen atoms.

As described above, the present disclosure performs dry etching of a copper thin film on the basis of conventional plasma etching. In particular, plasma flux (i.e., the ratio of radicals) control is realized through additional or simultaneous supply of the ACl_{b}-type first etching gas and the XH_{y}-type second etching gas. This allows a reaction between the generated copper chloride and hydrogen atoms to outpace the formation of copper chloride, thereby enabling efficient removal of copper chloride

According to one embodiment of the present disclosure, the ACl_{b}-type first etching gas supplies Cl⁺ ions during plasma processing, and may include any one selected from HCl, Cl₂, BCl₃, and CCl₄, or a mixture of at least two thereof.

Additionally, according to one embodiment of the present disclosure, the XH_{y}-type second etching gas supplies H⁺ ions during plasma processing, and may include any one selected from NH₃, CH₄, C₂H₄, C₃H₈, C₄H₁₀, and CₘHₙ, or a mixture thereof.

The present disclosure is not limited to the materials listed above, and any material capable of supplying Cl⁺ ions may be used as the first etching gas and any material capable of supplying H⁺ ions may be used as the second etching gas.

Additionally, according to one embodiment of the present disclosure, a plasma generated by supplying the ACl_{b}-type first etching gas and the XH_{y}-type second etching gas satisfies the following relationship: 0.5N(Cl+)≤N(H+) (where N(H+) denotes the flux of H⁺ ions and N(Cl+) denotes the flux of Cl⁺ ions).

Herein, the reaction between copper chloride (CuClₓ) and hydrogen atoms is represented by the following reaction equations: Cu+Cl->CuClₓ (solid), 3CuClₓ (solid)+3H (gas)->Cu₃Cl₃ (gas)+3HCl (gas). As a result of these reactions, the solid copper chloride (CuClx) is removed by conversion into volatile reaction products including Cu₃Cl₃ (gas) and 3HCl (gas), thereby enabling smooth dry etching of the copper thin film.

According to the above reaction scheme, the flux of ions participating in the reaction should satisfy the condition of 0.5N(Cl+) ≤N(H+). When this condition is not satisfied, the formation rate of copper chloride exceeds the removal rate thereof, resulting in improper etching of the copper thin film and a significant reduction in etch rate.

In the present disclosure, when hydrogen molecules are supplied in order to induce the copper chloride removal reaction, the following reaction is induced: 3CuCl₂ (solid)+3/2H₂ (g)=Cu₃Cl₃ (g)+3HCl (g). However, since this reaction is endothermic (ΔH^{o}[kJ/mol]), the etching process does not proceed effectively.

Therefore, the present disclosure ensures efficient copper chloride removal by supplying hydrogen in an atomic state rather than in a molecular state through the additional introduction of the XH_{y}-type second etching gas.

The XH_{y}-type second etching gas is plasma-activated to form X⁺ and H⁺ ions, which induce the reaction between copper chloride and hydrogen atoms.

Meanwhile, according to one embodiment of the present disclosure, as the process temperature of the plasma etching process decreases, the formation rate of Cu₃Cl₃ becomes faster than the formation rate of copper chloride. That is, it has been observed that even at a temperature of 200° C. or lower, the formation of Cu₃Cl₃ occurs faster than the formation of copper chloride, thereby realizing a low-temperature process (including a room-temperature process).

Accordingly, problems associated with chamber contamination caused by re-condensation of etching by-products, which typically occur when copper chloride is forcibly vaporized by applying high-temperature thermal energy in conventional processes, can be suppressed.

Additionally, according to one embodiment of the present disclosure, in order to enhance the reactivity between the copper chloride and hydrogen atoms, a plasma source capable of increasing electron temperature (Te) may be used. By employing a high-density plasma with an increased electron temperature, the fluxes of Cl⁺ ions and H⁺ ions can be increased. When the XH_{y}-type gas is additionally supplied as the second etching gas in this state, the flux of H⁺ ions can be further increased, thereby accelerating the reaction for copper chloride removal.

By enhancing the reactivity for copper chloride removal through plasma flux control, the present disclosure eliminates the need for a high-electron-temperature plasma source, such as an electron cyclotron resonance (ECR), thereby allowing the use of a plasma source with a relatively lower electron temperature, such as inductively coupled plasma (ICP) and substantially expanding plasma source selection flexibility.

Additionally, according to one embodiment of the present disclosure, in order to enhance the reactivity between copper chloride and hydrogen atoms, the flux of H⁺ ions supplied by the first etching gas is smaller than that of Cl⁺ ions. To compensate for this imbalance, the second etching gas is additionally supplied at a flow rate higher than that of the first etching gas so as to sufficiently provide hydrogen ions.

When the first etching gas is supplied in an excessive amount, for example, by increasing the flow rate of HCl gas, the process pressure increases, which in turn lowers the electron temperature. As a result, the fluxes of both H⁺ ions and Cl⁺ ions, leading to a decrease in etch rate. Accordingly, the first etching gas is maintained at an optimal flow rate, while the supply of H⁺ ions with a smaller collision cross-section is preferentially increased to enhance reactivity, thereby minimizing factors related to the pressure increase.

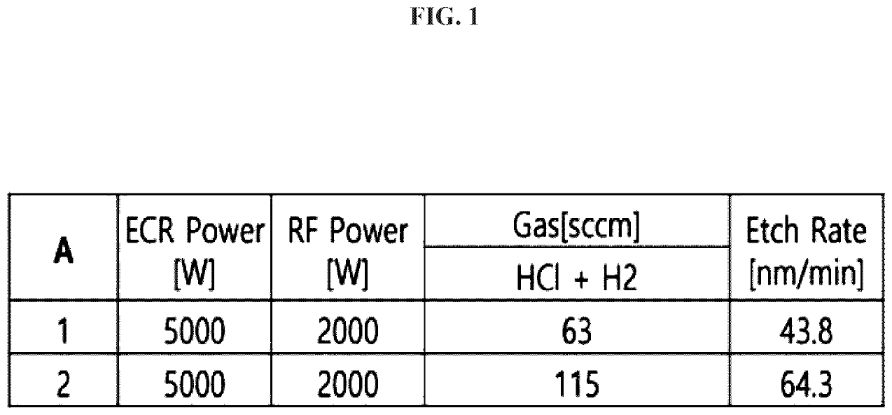

FIG. 1 is a table illustrating changes in etch rate as a function of the flow rate of HCl+H₂ gases under identical power conditions (ECR power of 5 kW and RF power of 2 kW).

According to one embodiment of the present disclosure, as the total flow rate of the HCl+H₂ gas increases, the etch rate increases. This indicates that increasing the total flow rate of etching gas (HCl+H₂) leads to an increase in the fluxes of Cl⁺ ions and H⁺ ions, thereby inducing a reaction between copper chloride and hydrogen atoms that proceeds faster than the formation of copper chloride. As a result, copper chloride can be removed more efficiently.

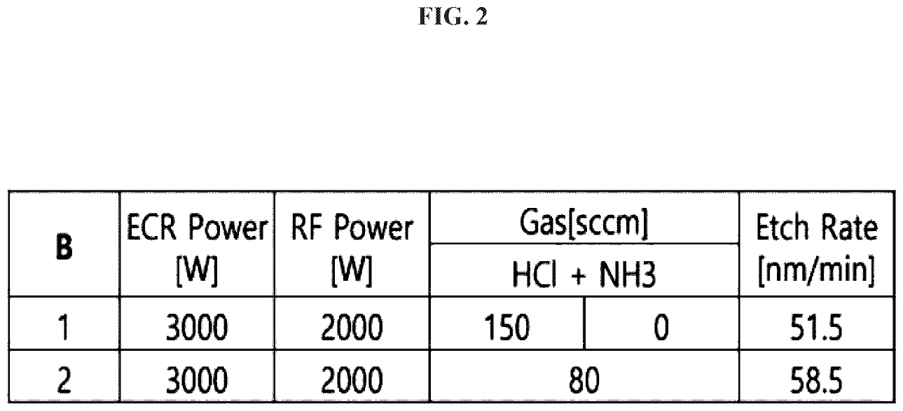

FIG. 2 is a table illustrating changes in etch rate under identical power conditions (ECR power of 3 kW and RF power of 2 kW) for a case in which an HCl etching gas is supplied at 150 sccm and a case in which an HCl+NH₃ etching gas including added NH₃ is supplied at 80 sccm, although the total flow rates are different.

According to one embodiment of the present disclosure, compared to the case in which only HCl as the first etching gas is used, an increased etch rate is achieved when NH₃ as the second etching gas is added to HCl, even though the total gas flow rate is lower. This result supports that the present disclosure facilitates efficient removal of copper chloride by supplying hydrogen in an atomic state rather than in a molecular state, and that the additional supply of the XH_{y}-type second etching gas is effective for this purpose. NH₃, the second etching gas, is plasma-activated to form N⁺ and H⁺ ions, which induce the reaction between copper chloride and hydrogen atoms.

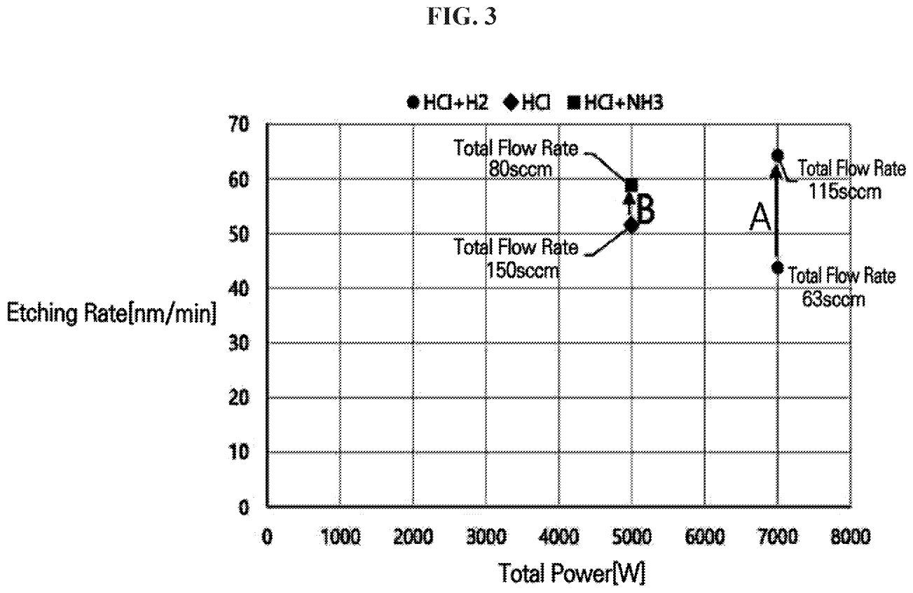

FIG. 3 is a comparative graph illustrating the experimental results of FIG. 1 and FIG. 2 together.

As described above, referring to FIG. 3, for the same type of etching gas, the etch rate increases with increasing total flow rate of the etching gas. Even at a lower total flow rate, the simultaneous use of HCl as the first etching gas and NH₃ as the second etching gas results in a higher etch rate than the use of HCl alone.

According to the method for dry etching the copper thin film by using plasma etching of the present disclosure, removal of copper chloride resulting from plasma etching of the copper thin film is achieved by enhancing the reactivity between the copper chloride and hydrogen atoms.

In particular, by additionally or simultaneously supplying an ACl_{b}-type first etching gas and an XH_{y}-type second etching gas, plasma flux (i.e., the ratio of radicals) control is realized, thereby promoting a reaction between copper chloride and hydrogen atoms that outpaces the formation of copper chloride and thus enabling efficient removal of copper chloride.

Furthermore, by rapidly removing copper chloride through control of ion flux, the need for cumbersome processes such as wet etching steps or high-temperature/auxiliary energy inputs conventionally required for copper chloride removal is eliminated, while simultaneously suppressing problems associated with chamber contamination caused by re-condensation during forced vaporization of copper chloride.

1. A method for dry etching a copper thin film by using plasma etching,
wherein during copper thin film etching using an ACl_{b}-type first etching gas, an XH_{y}-type second etching gas is supplied to enhance reactivity between copper chloride (CuClₓ) resulting from the copper thin film etching and hydrogen atoms.

2. The method of claim 1, wherein the ACl_{b}-type first etching gas is any one selected from HCl, Cl₂, BCl₃, and CCl₄, or a mixture of at least two thereof.

3. The method of claim 1, wherein the XH_{y}-type second etching gas is any one selected from NH₃, CH₄, C₂H₄, C₃H₈, C₄H₁₀, and CₘHₙ, or a mixture thereof.

4. The method of claim 1, wherein a plasma generated by supplying the ACl_{b}-type first etching gas and the XH_{y}-type second etching gas satisfies the following relationship:
0.5N(Cl+)≤N(H+)
wherein N(H+) denotes a flux of H⁺ ions and N(Cl+) denotes a flux of Cl⁺ ions.

5. The method of claim 1, wherein a reaction between the copper chloride (CuClₓ) and hydrogen atoms is represented by the following reaction equations:
Cu+Cl->CuClₓ (solid)
3CuClₓ (solid)+3H (gas)->Cu₃Cl₃ (gas)+3HCl (gas).

6. The method of claim 5, wherein as a process temperature of the plasma etching decreases, a formation rate of Cu₃Cl₃ becomes faster than a formation rate of the copper chloride.

7. The method of claim 1, wherein the reactivity between the copper chloride and hydrogen atoms is enhanced by increasing an electron temperature (Te).
